(19) United States
(12) Patent Application Publication
(10) Pub. No.: US 2024/0164024 A1
(43) Pub. Date: May 16, 2024

(54) METHOD FOR PRODUCING WIRING CIRCUIT BOARD, WIRING CIRCUIT BOARD WITH DUMMY PATTERN, AND ASSEMBLY SHEET

(71) Applicant: NITTO DENKO CORPORATION, Osaka (JP)

(72) Inventors: Ikuya HASHIMOTO, Osaka (JP); Ryosuke SASAOKA, Osaka (JP); Naoki SHIBATA, Osaka (JP)

(73) Assignee: NITTO DENKO CORPORATION, Osaka (JP)

(21) Appl. No.: 18/504,725

(22) Filed: Nov. 8, 2023

(30) Foreign Application Priority Data
Nov. 15, 2022 (JP) 2022-182968

(51) Int. Cl. H05K 3/10; H05K 1/11; H05K 3/00; H05K 3/18

(52) U.S. Cl. CPC H05K 3/108; H05K 1/119; H05K 3/002; H05K 3/18; H05K 3/28; H05K 2203/0723

(57) ABSTRACT

A method for producing a wiring circuit board includes a region setting step of setting a pattern forming region and an opening forming region in a support layer; an insulating layer forming step of forming a base insulating layer on the support layer in the pattern forming region; a pattern step of forming a conductive pattern having a first conductive layer and a second conductive layer on the base insulating layer; and an etching step of etching the support layer in the opening forming region, and in the pattern step, a dummy pattern is formed in the opening forming region.

### CROSS-REFERENCE TO RELATED APPLICATION

The present application claims priority from Japanese Patent Application No. 2022-182968 filed on Nov. 15, 2022, the contents of which are hereby incorporated by reference into this application.

### TECHNICAL FIELD

The present invention relates to a method for producing a wiring circuit board, a wiring circuit board with a dummy pattern, and an assembly sheet.

### BACKGROUND ART

Conventionally, a method for producing a printed wiring board in which a wiring pattern and a dummy pattern are formed on a support board has been known (ref: for example, Patent Document 1 below).

### CITATION LIST

### Patent Document

Patent Document 1: Japanese Unexamined Patent Publication No. 2003-273498

### SUMMARY OF THE INVENTION

### Problem to be Solved by the Invention

An opening may be desired to be formed in the printed wiring board as described in Patent Document 1. In this case, in the method as described in Patent Document 1, since the dummy pattern is formed outside a region where the printed wiring board is formed, it is difficult to achieve a uniform thickness of the wiring pattern formed in the vicinity of the opening.

The present invention provides a method for producing a wiring circuit board capable of achieving a uniform thickness of a conductive pattern formed in the vicinity of an opening, a wiring circuit board with a dummy pattern, and an assembly sheet.

### Means for Solving the Problem

The present invention [1] includes a method for producing a wiring circuit board including a region setting step of setting a pattern forming region and an opening forming region in a support layer; an insulating layer forming step of forming an insulating layer on the support layer at least in the pattern forming region; a pattern step of forming a conductive pattern having a first conductive layer having a first thickness and a second conductive layer having a second thickness different from the first thickness on the insulating layer in the pattern forming region, and including a first pattern step of forming the first conductive layer and a second pattern step of forming the second conductive layer; and an etching step of etching at least a portion of the support layer in the opening forming region, wherein in at least one of the first pattern step and the second pattern step, a dummy pattern is formed in the opening forming region.

According to such a method, the conductive pattern having the first conductive layer and the second conductive layer is formed on the insulating layer in the pattern forming region, and the dummy pattern is formed in the opening forming region.

Specifically, in at least one of the first pattern step and the second pattern step, the first conductive layer or the second conductive layer is formed in the pattern forming region, and the dummy pattern is formed in the opening forming region.

Thus, in at least one of the first pattern step and the second pattern step, it is possible to achieve the uniform metal ion concentration around the first conductive layer or the second conductive layer.

As a result, it is possible to achieve a uniform thickness of the conductive pattern formed in the vicinity of the opening.

The present invention [2] includes the method for producing a wiring circuit board of the above-described [1], wherein in the first pattern step, a dummy first conductive layer having the first thickness and constituting at least a portion of the dummy pattern is formed in the opening forming region.

According to such a method, in the first pattern step, the first conductive layer is formed in the pattern forming region, and the dummy first conductive layer is formed in the opening forming region.

Thus, in the first pattern step, it is possible to achieve the uniform metal ion concentration around the first conductive layer.

As a result, it is possible to achieve the uniform thickness of the first conductive layer of the conductive pattern formed in the vicinity of the opening.

The present invention [3] includes the method for producing a wiring circuit board of the above-described [1] or [2], wherein in the second pattern step, a dummy second conductive layer having the second thickness and constituting at least a portion of the dummy pattern is formed in the opening forming region.

According to such a method, in the second pattern step, the second conductive layer is formed in the pattern forming region, and the dummy second conductive layer is formed in the opening forming region.

Thus, in the second pattern step, it is possible to achieve the uniform metal ion concentration around the second conductive layer.

As a result, it is possible to achieve the uniform thickness of the second conductive layer of the conductive pattern formed in the vicinity of the opening.

The present invention [4] includes the method for producing a wiring circuit board of any one of the above-described [1] to [3] further including a cover insulating layer forming step of forming a cover insulating layer covering the conductive pattern and the dummy pattern.

According to such a method, the dummy pattern is also covered with the cover insulating layer covering the conductive pattern.

Therefore, it is possible to make the total thickness of the dummy pattern and the cover insulating layer thick.

Thus, it is possible to suppress a contact of the conductive pattern with its surrounding member by the dummy pattern and the cover insulating layer.

As a result, it is possible to protect the conductive pattern.

The present invention [5] includes the method for producing a wiring circuit board of any one of the above-described [1] to [4], wherein in the insulating layer forming step, the insulating layer is formed in the pattern forming region and the opening forming region, and in at least one of the first pattern step and the second pattern step, the dummy pattern is formed on the insulating layer in the opening forming region.

According to such a method, it is possible to support the dummy pattern by the insulating layer in the opening forming region.

Therefore, even when the entire support layer in the opening forming region is etched, it is possible to support the dummy pattern by the insulating layer in the opening forming region.

The present invention [6] includes the method for producing a wiring circuit board of the above-described [5], wherein in the region setting step, a product region including the pattern forming region and the opening forming region, and a frame region connected to the product region are further set in the support layer; in the etching step, the entire support layer in the opening forming region is etched to form an opening, and a portion of the support layer between the product region and the frame region is etched to form an outer shape of a wiring circuit board along a shape of the product region and to form a frame connected to the wiring circuit board along the shape of the frame region; and the method for producing a wiring circuit board further includes a cutting step of cutting the wiring circuit board from the frame and cutting the insulating layer in the opening from the wiring circuit board.

According to such a method, by etching the entire support layer in the opening forming region, the opening is formed, and by etching the support layer between the product region and the frame region, the outer shape of the wiring circuit board is formed, and the frame connected to the wiring circuit board is formed.

Then, the wiring circuit board is cut from the frame, and the insulating layer in the opening is cut from the wiring circuit board.

Thus, it is possible to easily remove the dummy pattern.

The present invention [7] includes the method for producing a wiring circuit board of any one of the above-described [1] to [4], wherein in the insulating layer forming step, the insulating layer is formed in the pattern forming region and the insulating layer is not formed in the opening forming region, and in at least one of the first pattern step and the second pattern step, the dummy pattern is formed on the support layer in the opening forming region.

According to such a method, it is possible to support the dummy pattern by the support layer in the opening forming region.

The present invention [8] includes the method for producing a wiring circuit board of the above-described [7], wherein in the etching step, the entire support layer in the opening forming region is etched.

According to such a configuration, by etching the entire support layer in the opening forming region, it is possible to easily remove dummy pattern.

The present invention [9] includes a wiring circuit board with a dummy pattern including a wiring circuit board having an opening and having a support layer disposed around the opening, an insulating layer disposed on the support layer in a thickness direction of the support layer, and a conductive pattern disposed on the insulating layer in the thickness direction; and a dummy pattern disposed in the opening, wherein the conductive pattern has a first conductive layer having a first thickness and a second conductive layer having a second thickness different from the first thickness.

According to such a configuration, the dummy pattern is disposed in the opening.

Therefore, it is possible to achieve the uniform thickness of at least one of the first conductive layer and the second conductive layer of the conductive pattern.

As a result, it is possible to achieve the uniform thickness of the conductive pattern formed in the vicinity of the opening.

The present invention [10] includes the wiring circuit board with a dummy pattern of the above-described [9], wherein the dummy pattern is made of a dummy first conductive layer having the first thickness or a dummy second conductive layer having the second thickness.

According to such a configuration, when the dummy pattern is made of the dummy first conductive layer, it is possible to achieve the uniform thickness of the first conductive layer of the conductive pattern.

Further, when the dummy pattern is made of the dummy second conductive layer, it is possible to achieve the uniform thickness of the second conductive layer of the conductive pattern.

The present invention [11] includes the wiring circuit board with a dummy pattern of the above-described [9], wherein the dummy pattern has a dummy first conductive layer having the first thickness, and a dummy second conductive layer having the second thickness and having at least a portion thereof disposed on the dummy first conductive layer.

According to such a configuration, it is possible to achieve the uniform thickness of both the first conductive layer and the second conductive layer of the conductive pattern.

As a result, it is possible to further achieve the uniform thickness of the conductive pattern formed in the vicinity of the opening.

The present invention [12] includes an assembly sheet including the wiring circuit board with a dummy pattern of any one of the above-described [9] to [11] and a frame supporting the wiring circuit board with a dummy pattern.

According to such a configuration, it is possible to handle the wiring circuit board with a dummy pattern together with the frame.

### Effect of the Invention

According to the method for producing a wiring circuit board of the present invention, it is possible to achieve a uniform thickness of a conductive pattern formed in the vicinity of an opening.

### BRIEF DESCRIPTION OF THE DRAWINGS

FIG. 1 shows a plan view of a wiring circuit board as one embodiment of the present invention.

FIG. 2 shows an A-A cross-sectional view of the wiring circuit board shown in FIG. 1.

FIGS. 3A and 3B show process views for illustrating a method for producing a wiring circuit board:

FIG. 3A illustrating a region setting step and

FIG. 3B illustrating an insulating layer forming step.

FIG. 4 shows a plan view of a support layer, a base insulating layer, and a dummy insulating layer shown in FIG. 3B, which is a B-B cross-sectional view of FIG. 4.

FIGS. 5A and 5B, subsequent to FIG. 3B, show process views for illustrating a method for producing a wiring circuit board:

FIG. 5A illustrating a first pattern step and

FIG. 5B illustrating a second pattern step.

FIG. 6 shows a plan view of a support layer, a base insulating layer, a dummy insulating layer, a conductive pattern, and a dummy pattern shown in FIG. 5B, which is a C-C cross-sectional view of FIG. 6.

FIGS. 7A and 7B, subsequent to FIG. 5B, show process views for illustrating a method for producing a wiring circuit board:

FIG. 7A illustrating a cover insulating layer forming step and

FIG. 7B illustrating an etching step.

FIGS. 8A to 8C show explanatory views for illustrating a modified example (1):

FIG. 8A illustrating a modified example in which a dummy pattern is made of a first dummy conductive layer,

FIG. 8B illustrating a modified example in which the dummy pattern is made of a second dummy conductive layer, and

FIG. 8C illustrating a modified example in which the dummy pattern made of the first dummy conductive pattern and the dummy pattern made of the second dummy conductive pattern are independently disposed, and illustrating a cross section corresponding to a D-D line of FIG. 6.

FIG. 9 shows an explanatory view for illustrating a modified example (2).

FIG. 10 shows an E-E cross-sectional view of FIG. 9.

FIGS. 11A to 11C show explanatory views for illustrating a modified example (3):

FIG. 11A illustrating an insulating layer forming step,

FIG. 11B illustrating a pattern forming step, and

FIG. 11C illustrating an etching step.

FIG. 12 shows an explanatory view for illustrating a modified example (6).

### DESCRIPTION OF EMBODIMENTS

### 1. Wiring Circuit Board

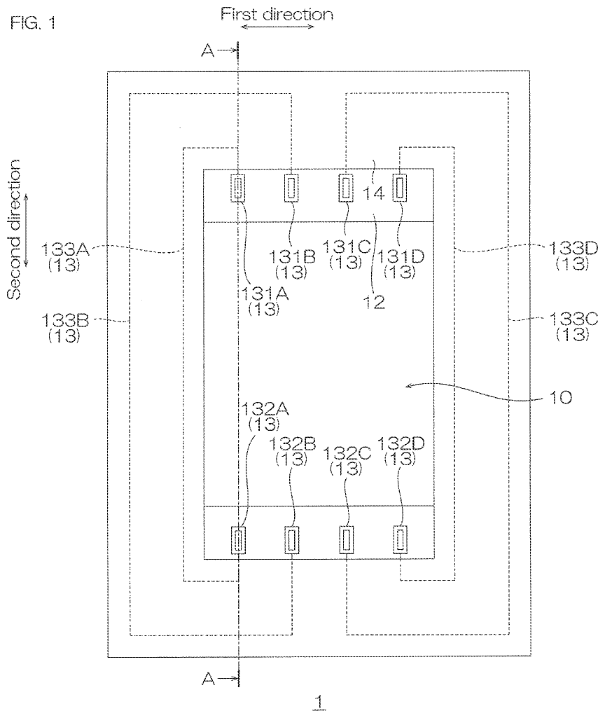

As shown in FIG. 1, a wiring circuit board 1 extends in a first direction and a second direction. In this embodiment, the wiring circuit board 1 has a generally rectangular shape. A shape of the wiring circuit board 1 is not limited. The wiring circuit board 1 has an opening 10.

In this embodiment, the opening 10 is disposed in the center of the wiring circuit board 1 in the first direction and in the center of the wiring circuit board 1 in the second direction. The opening 10 extends in the first direction and the second direction. The opening 10 has a generally rectangular shape. A position of the opening 10 in the wiring circuit board 1, and the shape of the opening 10 are not limited.

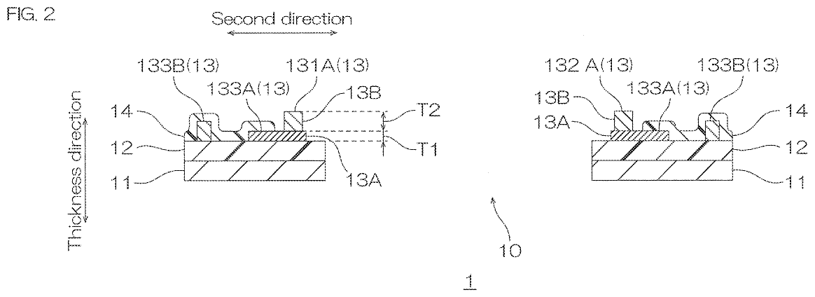

As shown in FIG. 2, the wiring circuit board 1 has a support layer 11, a base insulating layer 12 as one example of an insulating layer, a conductive pattern 13, and a cover insulating layer 14.

(1-1) Support Layer

The support layer 11 is disposed around the opening 10. The support layer 11 supports the base insulating layer 12, the conductive pattern 13, and the cover insulating layer 14. In this embodiment, the support layer 11 is made of a metal foil. Examples of a metal include stainless steel and copper alloys.

(1-2) Base Insulating Layer

The base insulating layer 12 is disposed on the support layer 11 in a thickness direction of the support layer 11. The thickness direction is perpendicular to the first direction and the second direction. The base insulating layer 12 is disposed between the support layer 11 and the conductive pattern 13 in the thickness direction. The base insulating layer 12 insulates the support layer 11 from the conductive pattern 13. The base insulating layer 12 is made of a resin. An example of the resin includes polyimide.

(1-3) Conductive Pattern

The conductive pattern 13 is disposed on the base insulating layer 12 in the thickness direction. The conductive pattern 13 is disposed on the opposite side to the support layer 11 with respect to the base insulating layer 12 in the thickness direction. As shown in FIG. 1, the conductive pattern 13 is disposed around the opening 10.

(1-3-1) Shape of Conductive Pattern

The shape of the conductive pattern 13 is not limited. In this embodiment, the conductive pattern 13 has a plurality of terminals 131A,131B, 131C, and 131D; a plurality of terminals 132A, 132B, 132C, and 132D; and a plurality of wirings 133A, 133B, 133C, and 133D. The number of terminals and the number of wirings are not limited.

In this embodiment, the terminals 131A, 131B, 131C, and 131D are disposed in one end portion of the wiring circuit board 1 in the second direction. The terminals 131A, 131B, 131C, and 131D are disposed on one side with respect to the opening 10 in the second direction. The terminals 131A, 131B, 131C, and 131D are disposed spaced from each other in the first direction. Each of the terminals 131A, 131B, 131C, and 131D has a square land shape.

In this embodiment, the terminals 132A, 132B, 132C, and 132D are disposed in the other end portion of the wiring circuit board 1 in the second direction. The terminals 132A, 132B, 132C, and 132D are disposed on the other side with respect to the opening 10 in the second direction. The terminals 132A, 132B, 132C, and 132D are disposed spaced from each other in the first direction. Each of the terminals 132A, 132B, 132C, and 132D has a square land shape.

One end of the wiring 133A is connected to the terminal 131A. The other end of the wiring 133A is connected to the terminal 132A. The wiring 133A electrically connects the terminal 131A to the terminal 132A.

One end of the wiring 133B is connected to the terminal 131B. The other end of the wiring 133B is connected to the terminal 132B. The wiring 133B electrically connects the terminal 131B to the terminal 132B.

One end of the wiring 133C is connected to the terminal 131C. The other end of the wiring 133C is connected to the terminal 132C. The wiring 133C electrically connects the terminal 131C to the terminal 132C.

One end of the wiring 133D is connected to the terminal 131D. The other end of the wiring 133D is connected to the terminal 132D. The wiring 133D electrically connects the terminal 131D to the terminal 132D.

(1-3-2) Layer Structure of Conductive Pattern

As shown in FIG. 2, the conductive pattern 13 has a first conductive layer 13A and a second conductive layer 13B.

The first conductive layer 13A is disposed on the base insulating layer 12 in the thickness direction. The first conductive layer 13A is made of a metal. An example of the metal includes copper. The first conductive layer 13A has a first thickness T1.

The first thickness T1 is, for example, 1 μm or more, preferably 3 μm or more, and for example, 50 μm or less, preferably 30 μm or less.

The second conductive layer 13B is disposed on the base insulating layer 12 or the first conductive layer 13A in the thickness direction. The second conductive layers 13B is made of the metal. An example of the metal includes copper. The second conductive layer 13B has a second thickness T2. The second thickness T2 is different from the first thickness T1. In this embodiment, the second thickness T2 is thicker than the first thickness T1.

The second thickness T2 is, for example, 2 μm or more, preferably 5 μm or more, and for example, 60 μm or less, preferably 40 μm or less.

In this embodiment, each of the terminals 131A, 131B, 131C, and 131D and each of the terminals 132A, 132B, 132C, and 132D is made of the first conductive layer 13A and the second conductive layer 13B. In each of the terminals 131A, 131B, 131C, and 131D and each of the terminals 132A, 132B, 132C, and 132D, the second conductive layer 13B is disposed on the first conductive layer 13A in the thickness direction.

Further, in this embodiment, the wirings 133A and 133D are made of the first conductive layer 13A. The wirings 133B and 133C are made of the second conductive layer 13B. That is, the thickness of the wirings 133A and 133D is different from the thickness of the wirings 133B and 133C.

(1-4) Cover Insulating Layer

As shown in FIG. 1, the cover insulating layer 14 covers the wirings 133A, 133B, 133C, and 133D. The cover insulating layer 14 is disposed on the base insulating layer 12 in the thickness direction. The cover insulating layer 14 does not cover the terminals 131A, 131B, 131C, and 131D and the terminals 132A, 132B, 132C, and 132D. The cover insulating layer 14 is made of the resin. An example of the resin includes polyimide.

### 2. Method for Producing Wiring Circuit Board

Next, a method for producing the wiring circuit board 1 is described.

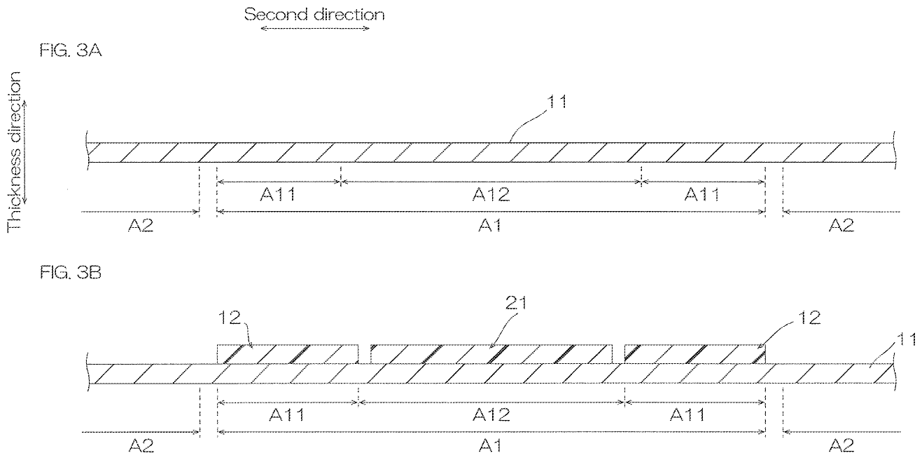

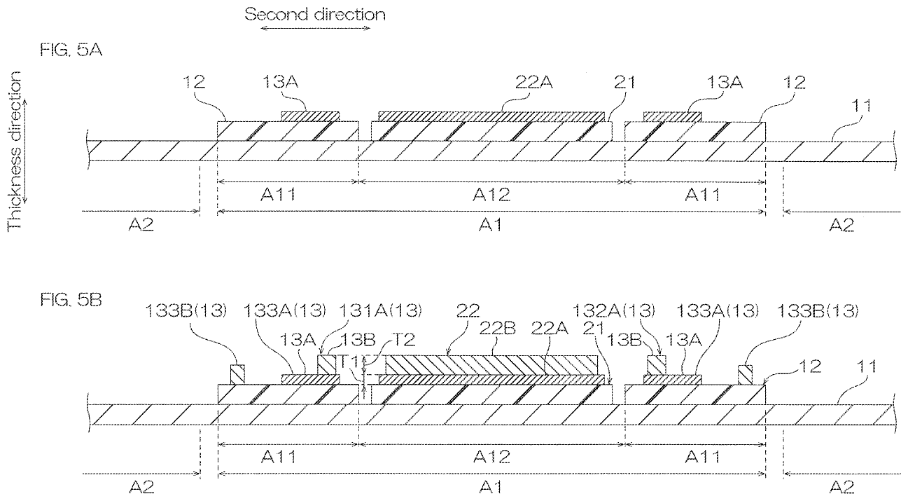

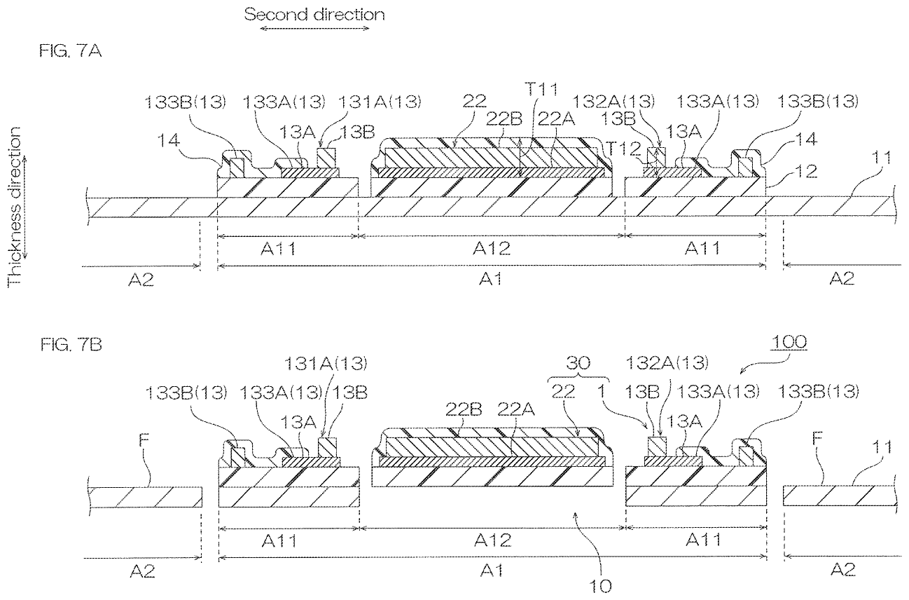

The method for producing the wiring circuit board 1 includes a region setting step (ref: FIG. 3A), an insulating layer forming step (ref: FIG. 3B), a pattern step (ref: FIGS. 5A and 5B), a cover insulating layer forming step (ref: FIG. 7A), an etching step (ref: FIG. 7B), and a cutting step.

(1) Region Setting Step

As shown in FIG. 3A, in the region setting step, a product region A1 and a frame region A2 are set in the support layer 11. In this embodiment, the support layer 11 is the metal foil drawn from a roll of the metal foil.

The above-described wiring circuit board 1 is produced in the product region A1. The product region A1 includes a pattern forming region A11 and an opening forming region A12. In other words, in the region setting step, the pattern forming region A11 and the opening forming region A12 are set in the support layer. The pattern forming region A11 is disposed outside the opening forming region A12. The pattern forming region A11 surrounds the opening forming region A12. The base insulating layer 12, the conductive pattern 13, and the cover insulating layer 14 described above are formed in the pattern forming region A11. The above-described opening 10 is formed in the opening forming region A12.

The frame region A2 is set outside the product region A1. The frame region A2 is connected to the product region A1. In the frame region A2, a frame supporting the wiring circuit board 1 is formed.

(2) Insulating Layer Forming Step

Next, as shown in FIG. 3B, in the insulating layer forming step, at least in the pattern forming region A11, an insulating layer is formed on the support layer 11. In this embodiment, the insulating layer is formed in the pattern forming region A11 and the opening forming region A12.

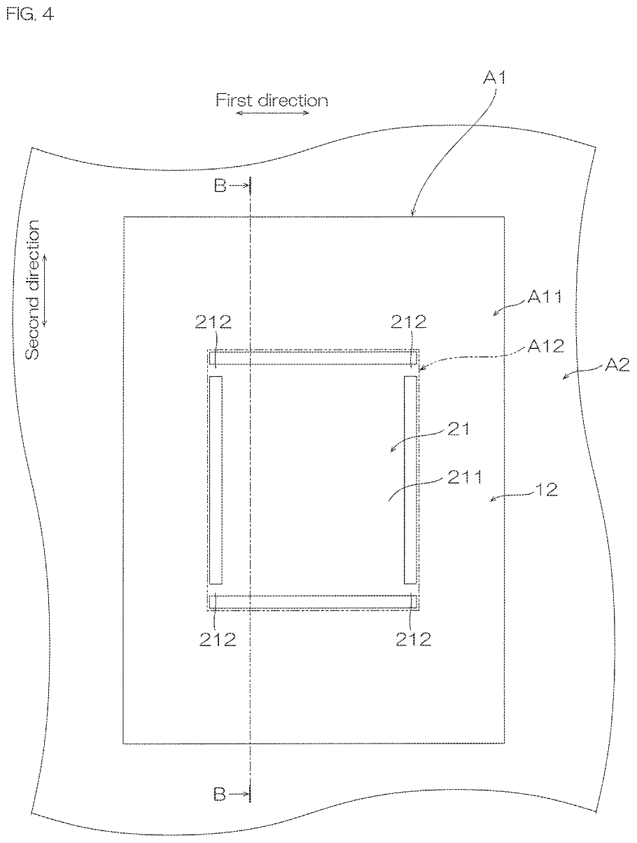

Specifically, as shown in FIG. 4, in the pattern forming region A11, the above-described base insulating layer 12 is formed, and in the opening forming region A12, a dummy insulating layer 21 is formed.

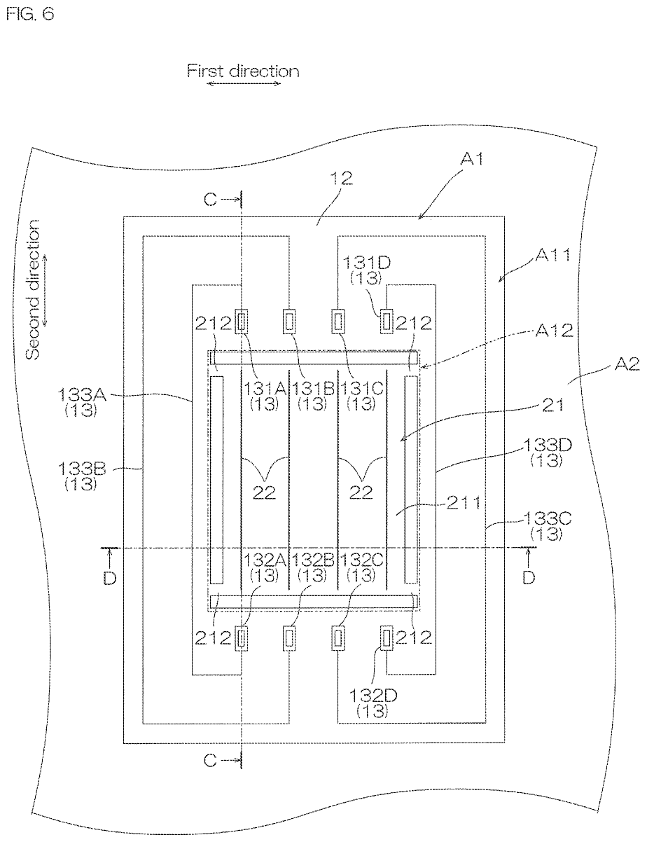

The dummy insulating layer 21 supports a dummy pattern 22 (ref: FIG. 6). The dummy pattern 22 is described later. The dummy insulating layer 21 has a support portion 211 and at least one connecting portion 212. In this embodiment, the dummy insulating layer 21 has the plurality of connecting portions 212.

The support portion 211 supports the dummy pattern 22. The support portion 211 is disposed away from the base insulating layer 12. In this embodiment, the support portion 211 has a generally rectangular shape. The shape of the support portion 211 is not limited.

Each of the plurality of connecting portions 212 is disposed between the support portion 211 and the base insulating layer 12. Each of the plurality of connecting portions 212 is connected to the support portion 211 and the base insulating layer 12. Thus, the dummy insulating layer 21 is connected to the base insulating layer 12.

In order to form the base insulating layer 12 and the dummy insulating layer 21, first, a solution (varnish) of a photosensitive resin is coated on the support layer 11 and dried, thereby forming a coating film of the photosensitive resin. Next, the coating film of the photosensitive resin is exposed to light and developed. Thus, the base insulating layer 12 and the dummy insulating layer 21 are formed on the support layer 11.

(3) Pattern Step

Next, as shown in FIGS. 5A and 5B, in the pattern step, the conductive pattern 13 is formed on the base insulating layer 12 in the pattern forming region A11, and the dummy pattern 22 (ref: FIG. 6) is formed on the dummy insulating layer 21 in the opening forming region A12 by electrolytic plating.

As shown in FIG. 5B, the dummy pattern 22 has a dummy first conductive layer 22A and a dummy second conductive layer 22B.

The dummy first conductive layer 22A is disposed on the dummy insulating layer 21 in the thickness direction. The dummy first conductive layer 22A is made of the same material as the first conductive layer 13A of the conductive pattern 13. The dummy first conductive layer 22A has the first thickness T1. That is, the dummy first conductive layer 22A has the same thickness as the first conductive layer 13A of the conductive pattern 13.

The dummy second conductive layer 22B is disposed on the dummy first conductive layer 22A in the thickness direction. In this embodiment, the entire dummy second conductive layer 22B is disposed on the dummy first conductive layer 22A in the thickness direction. The dummy second conductive layer 22B is made of the same material as the second conductive layer 13B of the conductive pattern 13. The dummy second conductive layer 22B has the second thickness T2. That is, the dummy second conductive layer 22B has the same thickness as the second conductive layer 13B of the conductive pattern 13.

In order to form the conductive pattern 13 and the dummy pattern 22, as shown in FIG. 5A, in the pattern step, first, the first pattern step is carried out. That is, the pattern step includes the first pattern step.

In the first pattern step, the first conductive layer 13A is formed on the base insulating layer 12 in the pattern forming region A11, and the dummy first conductive layer 22A is formed on the dummy insulating layer 21 in the opening forming region A12.

In order to form the first conductive layer 13A and the dummy first conductive layer 22A, first, a seed layer is formed on the surfaces of the base insulating layer 12 and the dummy insulating layer 21. The seed layer is formed, for example, by sputtering. Examples of a material for the seed layer include chromium, copper, nickel, titanium, and alloys of these.

Next, a plating resist is attached onto the base insulating layer 12 and the dummy insulating layer 21 on which the seed layer is formed, and the plating resist is exposed to light, while portions where the first conductive layer 13A and the dummy first conductive layer 22A are formed are shielded.

Next, the exposed plating resist is developed. Then, the plating resist of the shielded portions is removed, and the seed layer is exposed to the portions where the first conductive layer 13A and the dummy first conductive layer 22A are formed. The plating resist of the exposed portions, that is, the portions where the first conductive layer 13A and the dummy first conductive layer 22A are not formed remains.

Next, the first conductive layer 13A and the dummy first conductive layer 22A are formed on the exposed seed layer by the electrolytic plating.

At this time, the first conductive layer 13A is formed together with the dummy first conductive layer 22A. Therefore, in a plating solution, it is possible to achieve the uniform metal ion concentration around the product region A1, and to achieve the uniform thickness of the first conductive layer 13A.

Then, after the electrolytic plating is completed, the plating resist is peeled.

Next, as shown in FIG. 5B, in the pattern step, a second pattern step is carried out. That is, the pattern step includes the second pattern step.

In the second pattern step, the second conductive layer 13B is formed in the pattern forming region A11, and the dummy second conductive layer 22B is formed in the opening forming region A12. That is, in this embodiment, in the first pattern step and the second pattern step, the dummy pattern 22 is formed.

In order to form the second conductive layer 13B and the dummy second conductive layer 22B, first, the plating resist is attached onto the base insulating layer 12 and the dummy insulating layer 21 so as to cover the first conductive layer 13A and the dummy first conductive layer 22A, and the plating resist is exposed to light, while the portions where the second conductive layer 13B and the dummy second conductive layer 22B are formed are shielded.

Next, the exposed plating resist is developed. Then, the plating resist of the shielded portions is removed, the seed layer or the first conductive layer 13A is exposed to the portion where the second conductive layer 13B is formed, and the dummy first conductive layer 22A is exposed to the portion where the dummy second conductive layer 22B is formed. The plating resist of the exposed portions, that is, the portions where the second conductive layer 13B and the dummy second conductive layer 22B are not formed remains.

Next, the second conductive layer 13B is formed on the exposed seed layer or the exposed first conductive layer 13A, and the dummy second conductive layer 22B is formed on the exposed dummy first conductive layer 22A by the electrolytic plating.

At this time, the second conductive layer 13B is formed together with the dummy second conductive layer 22B. Therefore, it is possible to achieve the uniform thickness of the second conductive layer 13B.

Then, after the electrolytic plating is completed, the plating resist is peeled.

Next, the seed layer which is exposed by peeling the plating resist is removed by etching.

Thus, as shown in FIG. 6, the conductive pattern 13 is formed on the base insulating layer 12, and the dummy pattern 22 is formed on the dummy insulating layer 21.

(4) Cover Insulating Layer Forming Step

Next, as shown in FIG. 7A, in the cover insulating layer forming step, the cover insulating layer 14 is formed on the base insulating layer 12, the conductive pattern 13, and the dummy pattern 22 in the same manner as the formation of the base insulating layer 12.

A total thickness T11 of the dummy pattern 22 and the cover insulating layer 14 is thicker than each thickness T12 of the terminals 131A, 131B, 131C, and 131D and the terminals 132A, 132B, 132C, and 132D.

Therefore, it is possible to suppress a contact of each of the terminals 131A, 131B, 131C, and 131D and each of the terminals 132A, 132B, 132C, and 132D with its surrounding member by the dummy pattern 22 and the cover insulating layer 14. Specifically, when the support layer 11 in which the base insulating layer 12, the conductive pattern 13, the dummy pattern 22, and the cover insulating layer 14 are formed is wound around in a roll shape, it is possible to suppress the contact of each of the terminals 131A, 131B, 131C, and 131D and each of the terminals 132A, 132B, 132C, and 132D with the support layer 11 by the dummy pattern 22 and the cover insulating layer 14.

Thus, it is possible to protect each of the terminals 131A, 131B, 131C, and 131D and each of the terminals 132A, 132B, 132C, and 132D.

(4) Etching Step

Next, as shown in FIG. 7B, in the etching step, by etching the entire support layer 11 in the opening forming region A12, the opening 10 is formed. Further, in the etching step, by etching the support layer 11 between the product region A1 and the frame region A2, an outer shape of the wiring circuit board 1 is formed along the shape of the product region A1, and a frame F is formed along the shape of the frame region A2.

In order to etch the support layer 11, the portion which is not etched in the support layer 11 is covered with an etching resist, and the support layer 11 is immersed in an etching solution.

Then, the entire support layer 11 in the opening forming region A12 is etched, and the opening 10 is formed.

At this time, since the dummy pattern 22 is supported by the dummy insulating layer 21, even when the entire support layer 11 in the opening forming region A12 is etched, the dummy pattern 22 does not fall into the etching solution. Therefore, it is possible to provide the dummy pattern 22 in the opening forming region A12 even without a device for collecting the dummy pattern 22 which falls in the etching solution.

Further, a portion of the support layer 11 between the product region A1 and the frame region A2 is etched to form the outer shape of the wiring circuit board 1 and the frame F. The frame F is connected to the wiring circuit board 1. Thus, a wiring circuit board 30 with a dummy pattern including the wiring circuit board 1 having the opening 10, and the dummy pattern 22 disposed in the opening 10 is obtained; and an assembly sheet 100 having the wiring circuit board 30 with a dummy pattern, and the frame F supporting the wiring circuit board 30 with a dummy pattern is obtained.

(5) Cutting Step

Next, as shown in FIG. 2, in the cutting step, the wiring circuit board 1 is cut from the frame F, and the dummy insulating layer 21 in the opening 10 is cut from the wiring circuit board 1.

Thus, the wiring circuit board 1 is obtained.

A method for cutting the wiring circuit board 1 from the frame F, and a method for cutting the dummy insulating layer 21 from the wiring circuit board 1 are not limited. For example, a connecting portion between the wiring circuit board 1 and the frame F, and the connecting portion 212 of the dummy insulating layer 21 (ref: FIG. 6) are cut with a cutter, by punching with a metal mold, laser processing, or the like, so that the wiring circuit board 1 is cut from the frame F and the dummy insulating layer 21 is cut from the wiring circuit board 1. Traces of cutting the dummy insulating layer 21 may remain in the inner surface of the opening 10 of the wiring circuit board 1.

### 3. Function and Effect

(1) According to the method for producing the wiring circuit board 1, as shown in FIGS. 5A and 5B, the conductive pattern 13 consisting of the first conductive layer 13A and the second conductive layer 13B is formed on the base insulating layer 12 in the pattern forming region A11, and the dummy pattern 22 consisting of the dummy first conductive layer 22A and the dummy second conductive layer 22B is formed on the dummy insulating layer 21 in the opening forming region A12.

Specifically, in the first pattern step, the first conductive layer 13A is formed in the pattern forming region A11, and the dummy first conductive layer 22A is formed in the opening forming region A12 by the electrolytic plating. Next, in the second pattern step, the second conductive layer 13B is formed in the pattern forming region A11, and the dummy second conductive layer 22B is formed in the opening forming region A12 by the electrolytic plating.

Thus, in the first pattern step and the second pattern step, it is possible to achieve the uniform metal ion concentration around the first conductive layer 13A or the second conductive layer 13B.

As a result, it is possible to achieve the uniform thickness of the conductive pattern 13 formed in the vicinity of the opening 10.

(2) According to the method for producing the wiring circuit board 1, as shown in FIG. 7B, the dummy pattern 22 is also covered with the cover insulating layer 14 covering the wirings 133A, 133B, 133C, and 133D of the conductive pattern 13.

Therefore, it is possible to make the total thickness T11 of the dummy pattern 22 and the cover insulating layer 14 thicker than the thickness T12 of each of the terminals 131A, 131B, 131C, and 131D and each of the terminals 132A, 132B, 132C, and 132D.

Thus, it is possible to suppress the contact of each of the terminals 131A, 131B, 131C, and 131D and each of the terminals 132A, 132B, 132C, and 132D with its surrounding member by the dummy pattern 22 and the cover insulating layer 14.

As a result, it is possible to protect each of the terminals 131A, 131B, 131C, and 131D and each of the terminals 132A, 132B, 132C, and 132D.

(3) According to the method for producing the wiring circuit board 1, as shown in FIG. 7B, it is possible to support the dummy pattern 22 by the dummy insulating layer 21 in the opening forming region A12.

Therefore, even when the entire support layer 11 in the opening forming region A12 is etched, it is possible to support the dummy pattern 22 by the dummy insulating layer 21.

(4) According to the method for producing the wiring circuit board 1, as shown in FIG. 7B, by etching the entire support layer 11 in the opening forming region A12, the opening 10 is formed, and by etching the support layer 11 between the product region A1 and the frame region A2, the outer shape of the wiring circuit board 1 is formed, and the frame F connected to the wiring circuit board 1 is formed.

Then, as shown in FIG. 2, the wiring circuit board 1 is cut from the frame F, and the dummy insulating layer 21 in the opening 10 is cut from the wiring circuit board 1.

Thus, it is possible to easily remove the dummy pattern 22.

(5) According to the wiring circuit board 30 with a dummy pattern, as shown in FIG. 7B, the dummy pattern 22 is disposed in the opening 10.

Therefore, it is possible to achieve the uniform thickness of the conductive pattern 13 formed in the vicinity of the opening 10.

(6) According to the wiring circuit board 30 with a dummy pattern, as shown in FIG. 7B, the dummy pattern 22 has the dummy first conductive layer 22A, and the dummy second conductive layer 22B disposed on the dummy first conductive layer 22A.

Therefore, it is possible to achieve the uniform thickness of both the first conductive layer 13A and the second conductive layer 13B of the conductive pattern 13.

As a result, it is possible to further achieve the uniform thickness of the conductive pattern 13 formed in the vicinity of the opening 10.

(7) According to the assembly sheet 100, as shown in FIG. 7B, the frame F supporting the wiring circuit board 30 with a dummy pattern is provided.

Therefore, it is possible to handle the wiring circuit board 30 with a dummy pattern together with the frame F.

### 4. Modified Examples

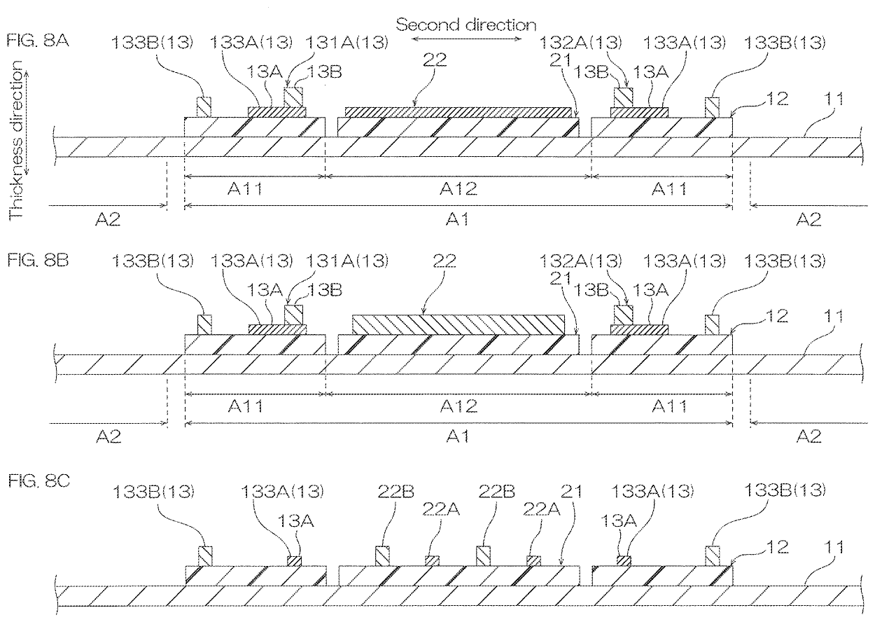

Next, modified examples are described with reference to FIGS. 8A to 12. In each modified example, the same reference numerals are provided for members corresponding to each of those in the above-described embodiment, and their detailed description is omitted.

(1) As shown in FIG. 8A, the dummy pattern 22 may also be made of the dummy first conductive layer 22A.

When the dummy pattern 22 is made of the dummy first conductive layer 22A, it is possible to achieve the uniform thickness of the first conductive layer 13A of the conductive pattern 13.

Further, as shown in FIG. 8B, the dummy pattern 22 may also be made of the dummy second conductive layer 22B.

When the dummy pattern 22 is made of the dummy second conductive layer 22B, it is possible to achieve the uniform thickness of the second conductive layer 13B of the conductive pattern 13.

Further, as shown in FIG. 8C, the wiring circuit board 30 with a dummy pattern may also have the dummy pattern 22 made of the dummy first conductive layer 22A and the dummy pattern 22 made of the dummy second conductive layer 22B independently of each other.

In this case, it is possible to achieve the uniform thickness of both the first conductive layer 13A and the second conductive layer 13B of the conductive pattern 13.

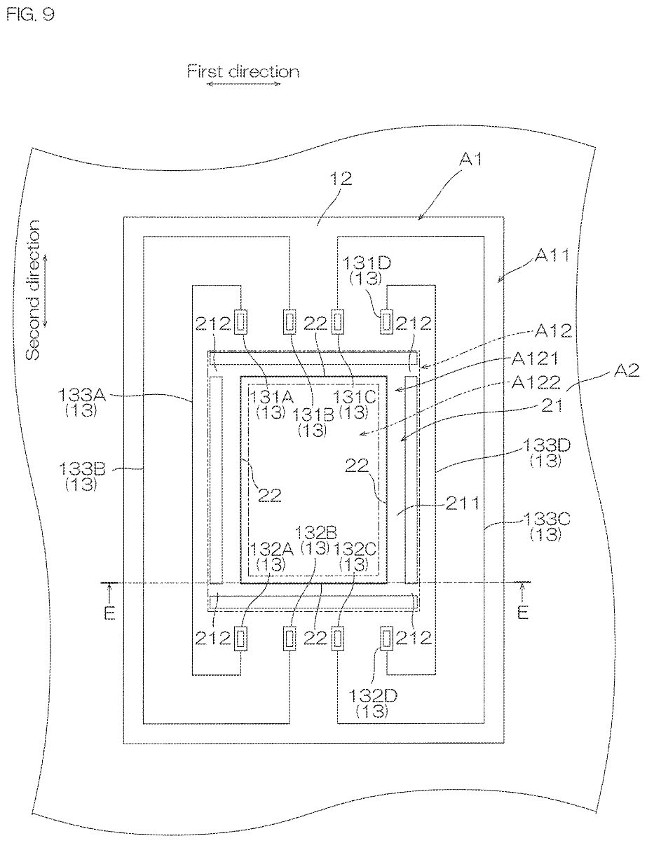

(2) As shown in FIG. 9, it is also possible to form the dummy pattern 22 in a peripheral edge portion A121 of the opening forming region A12, and not to form the dummy pattern 22 in a central portion A122 of the opening forming region A12. The peripheral edge portion A121 is a portion located between the central portion A122 and the conductive pattern 13.

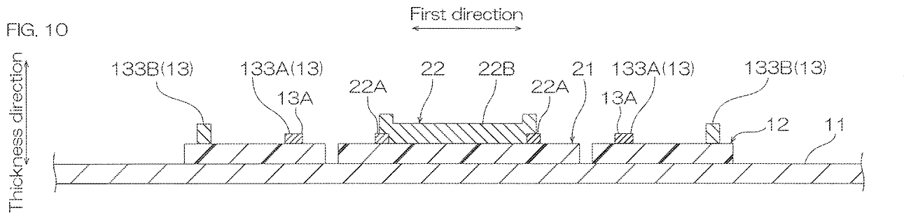

In this case, as shown in FIG. 10, the dummy pattern 22 extending in the second direction may be formed from the dummy first conductive layer 22A, and the dummy pattern 22 extending in the first direction may be also formed from the dummy second conductive layer 22B. The end portion of the dummy pattern 22 extending in the first direction may be also disposed on the end portion of the dummy pattern 22 extending in the second direction. That is, a portion of the dummy second conductive layer 22B may be also disposed on the dummy first conductive layer 22A.

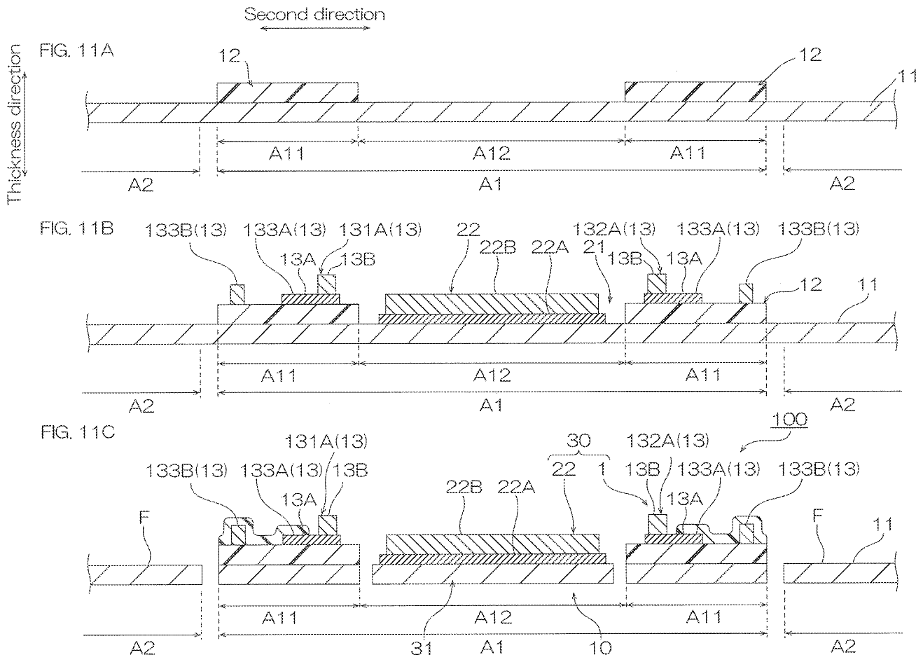

(3) As shown in FIG. 11A, in the insulating layer forming step, the base insulating layer 12 may be formed in the pattern forming region A11, and the dummy insulating layer 21 may also not be formed in the opening forming region A12.

In this case, as shown in FIG. 11B, in the pattern step, the dummy pattern 22 is formed on the support layer 11 in the opening forming region A12.

Then, as shown in FIG. 11C, in the etching step, a portion of the support layer 11 in the opening forming region A12 is etched. Specifically, a portion of the support layer 11 in the opening forming region A12 is etched along a border between the pattern forming region A11 and the opening forming region A12. Thus, a dummy support layer 31 supporting the dummy pattern 22 is formed in the opening forming region A12.

The dummy support layer 31 is made of the same material as the support layer 11, and has the same shape as the above-described dummy insulating layer 21.

In the modified example, in the cutting step, the dummy support layer 31 is cut from the wiring circuit board 1.

(4) As shown in FIG. 11C, the cover insulating layer 14 may also not cover the dummy pattern 22.

(5) In the etching step (ref: FIG. 7B) of the above-described embodiment, by etching a portion of the support layer 11 in the opening forming region A12, the dummy support layer 31 (ref: FIG. 11C) having the same shape as the dummy insulating layer 21 may be also formed in the same manner as the above-described modified example (3).

(6) In the etching step of the above-described modified example (3), the entire support layer 11 in the opening forming region A12 may be also etched without forming the dummy support layer 31.

Specifically, as shown in FIG. 11A, in the insulating layer forming step, the base insulating layer 12 is formed in the pattern forming region A11, and the dummy insulating layer 21 is not formed in the opening forming region A12.

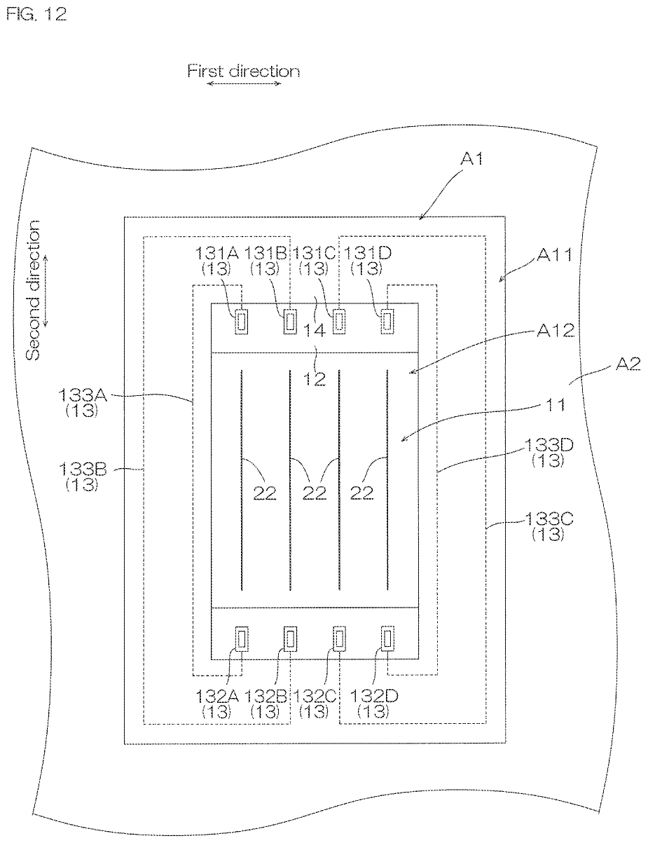

Next, as shown in FIG. 12, in the pattern step, the dummy pattern 22 is formed on the support layer 11 in the opening forming region A12.

Then, in the etching step, the entire support layer 11 in the opening forming region A12 is etched.

In this case, the dummy pattern 22 may fall into the etching solution. When the dummy pattern 22 falls into the etching solution, it is preferable to use a device for collecting the dummy pattern 22 which falls into the etching solution.

According to this modified example, by etching the entire support layer 11 in the opening forming region A12, it is possible to easily remove the dummy pattern 22.

(7) The dummy pattern 22 may be formed not only in the opening forming region A12 but also in the frame region A2.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### DESCRIPTION OF REFERENCE NUMERALS

1 Wiring circuit board
10 Opening
11 Support layer
12 Base insulating layer
13 Conductive pattern
13A First conductive layer
13B Second conductive layer
22 Dummy pattern
22A Dummy first conductive layer
22B Dummy second conductive layer
A1 Product region
A2 Frame region
A11 Pattern forming region
A12 Opening forming region
F Frame

1. A method for producing a wiring circuit board comprising:
a region setting step of setting a pattern forming region and an opening forming region in a support layer;
an insulating layer forming step of forming an insulating layer on the support layer at least in the pattern forming region;
a pattern step of forming a conductive pattern having a first conductive layer having a first thickness and a second conductive layer having a second thickness different from the first thickness on the insulating layer in the pattern forming region, and including a first pattern step of forming the first conductive layer and a second pattern step of forming the second conductive layer; and
an etching step of etching at least a portion of the support layer in the opening forming region, wherein
in at least one of the first pattern step and the second pattern step, a dummy pattern is formed in the opening forming region.

2. The method for producing a wiring circuit board according to claim 1, wherein
in the first pattern step, a dummy first conductive layer having the first thickness and constituting at least a portion of the dummy pattern is formed in the opening forming region.

3. The method for producing a wiring circuit board according to claim 1, wherein
in the second pattern step, a dummy second conductive layer having the second thickness and constituting at least a portion of the dummy pattern is formed in the opening forming region.

4. The method for producing a wiring circuit board according to claim 1 further comprising:
a cover insulating layer forming step of forming a cover insulating layer covering the conductive pattern and the dummy pattern.

5. The method for producing a wiring circuit board according to claim 1, wherein
in the insulating layer forming step, the insulating layer is formed in the pattern forming region and the opening forming region, and
in at least one of the first pattern step and the second pattern step, the dummy pattern is formed on the insulating layer in the opening forming region.

6. The method for producing a wiring circuit board according to claim 5, wherein
in the region setting step, a product region including the pattern forming region and the opening forming region, and a frame region connected to the product region are further set in the support layer;
in the etching step, the entire support layer in the opening forming region is etched to form an opening, and a portion of the support layer between the product region and the frame region is etched to form an outer shape of a wiring circuit board along a shape of the product region and to form a frame connected to the wiring circuit board along the shape of the frame region; and
the method for producing a wiring circuit board further includes a cutting step of cutting the wiring circuit board from the frame and cutting the insulating layer in the opening from the wiring circuit board.

7. The method for producing a wiring circuit board according to claim 1, wherein
in the insulating layer forming step, the insulating layer is formed in the pattern forming region and the insulating layer is not formed in the opening forming region, and
in at least one of the first pattern step and the second pattern step, the dummy pattern is formed on the support layer in the opening forming region.

8. The method for producing a wiring circuit board according to claim 7, wherein
in the etching step, the entire support layer in the opening forming region is etched.

9. A wiring circuit board with a dummy pattern comprising:
a wiring circuit board having an opening and having a support layer disposed around the opening, an insulating layer disposed on the support layer in a thickness direction of the support layer, and a conductive pattern disposed on the insulating layer in the thickness direction; and
a dummy pattern disposed in the opening, wherein
the conductive pattern has
a first conductive layer having a first thickness and
a second conductive layer having a second thickness different from the first thickness.

10. The wiring circuit board with a dummy pattern according to claim 9, wherein
the dummy pattern is made of a dummy first conductive layer having the first thickness or a dummy second conductive layer having the second thickness.

11. The wiring circuit board with a dummy pattern according to claim 9, wherein
the dummy pattern has
a dummy first conductive layer having the first thickness, and
a dummy second conductive layer having the second thickness and having at least a portion thereof disposed on the dummy first conductive layer.

12. An assembly sheet comprising:
the wiring circuit board with a dummy pattern according to claim 9 and
a frame supporting the wiring circuit board with a dummy pattern.
